(19) United States
(12) Patent Application Publication
(10) Pub. No.: US 2023/0020140 A1
(43) Pub. Date: Jan. 19, 2023

(54) SEMICONDUCTOR TEST STRUCTURE AND METHOD FOR MANUFACTURING SAME

(71) Applicant: CHANGXIN MEMORY TECHNOLOGIES, INC., Hefei City (CN)

(72) Inventor: Shuhao ZHANG, Hefei City (CN)

(73) Assignee: CHANGXIN MEMORY TECHNOLOGIES, INC., Hefei City (CN)

(21) Appl. No.: 17/648,799

(22) Filed: Jan. 24, 2022

Related U.S. Application Data
(63) Continuation of application No. PCT/CN2021/109315, filed on Jul. 29, 2021.

(30) Foreign Application Priority Data
Jul. 16, 2021 (CN) 202110809038.3

(51) Int. Cl. H01L 29/80; H01L 29/812; H01L 29/66; H01L 29/40

(52) U.S. Cl. CPC H01L 29/806; H01L 29/812; H01L 29/66848; H01L 29/401

(57) ABSTRACT

A semiconductor test structure includes a field-effect transistor and a metal connection structure. The field-effect transistor includes a substrate with first doping type, a gate located on a surface of the substrate, and a source region with a second doping type and a drain region with the second doping type in the substrate, the source region and the drain region are located on two sides of the gate, respectively. The metal connection structure is connected with the gate; the metal connection structure forms a Schottky contact with the substrate.

### CROSS-REFERENCE TO RELATED APPLICATIONS

The present disclosure is a continuation of International Patent Application No. PCT/CN2021/109315 filed on Jul. 29, 2021, which claims priority to Chinese Patent Application No. 202110809038.3 filed on Jul. 16, 2021. The disclosures of the above-referenced applications are hereby incorporated by reference in their entirety.

### BACKGROUND

As the semiconductor manufacturing process enters a level of deep-submicron, a plasma process is used more and more widely. The plasma process is mainly applied in fields of ultraviolet lithography, plasma etching, ion implantation, etc. However, plasma charges may be generated in the plasma process. A gate leakage current may be generated in a gate dielectric layer between a gate and a substrate when conductors having the plasma charges accumulated are directly connected with the gate of a device. When the accumulated charges exceed a certain amount, the gate leakage current may damage the gate dielectric layer, as a result, reliability and a service life of the device, even the entire chip, may be seriously reduced. The situation is usually called as Plasma Induced Damage (PID) or Process Antenna Effect (PAE).

### SUMMARY

The present disclosure relates to a semiconductor test structure and a method for manufacturing the same.

In a first aspect, embodiments of the disclosure provide a semiconductor test structure, the semiconductor test structure includes a field-effect transistor and a metal connection structure.

The field-effect transistor includes a substrate with a first doping type, a gate located on a surface of the substrate, and a source region with a second doping type and a drain region with the second doping type in the substrate. The source region and the drain region are located on two sides of the gate, respectively.

The metal connection structure is connected with the gate, and the metal connection structure forms a Schottky contact with the substrate.

In a second aspect, embodiments of the disclosure provide a method for manufacturing a semiconductor test structure. The method includes the following operations.

A semiconductor structure is provided. The semiconductor structure includes a field-effect transistor and a dielectric layer covering the field-effect transistor. The field-effect transistor includes a substrate with a first doping type, a gate located on a surface of the substrate, and a source region with a second doping type and a drain region with the second doping type in the substrate, the source region and the drain region being located on two sides of the gate, respectively.

A metal connection structure in contact with the substrate and the gate is formed in the dielectric layer.

The metal connection structure forms a Schottky contact with the substrate.

### BRIEF DESCRIPTION OF THE DRAWINGS

Unless otherwise specified, in the accompanying drawings, the same reference numerals in a plurality of drawings represent same or similar components or elements. These drawings are not necessarily drawn to scale. It should be understood that these drawings only describe some implementations disclosed in the disclosure, and should not be considered as limitations to the scope of the disclosure.

FIG. 1A is a top view of a semiconductor test structure in some implementations.

FIG. 1B is a section view of a semiconductor test structure in some implementations.

FIG. 2 is a schematic structure diagram of a cross-section of a semiconductor test structure provided in embodiments of the disclosure.

FIG. 3 is a schematic flowchart of an implementation of a method for manufacturing a semiconductor test structure provided in embodiments of the disclosure.

FIG. 4A is a first partial cross-sectional schematic diagram of a process for manufacturing a semiconductor test structure in a specific example of the disclosure.

FIG. 4B is a second partial cross-sectional schematic diagram of a process for manufacturing a semiconductor test structure in a specific example of the disclosure.

FIG. 4C is a third partial cross-sectional schematic diagram of a process for manufacturing a semiconductor test structure in a specific example of the disclosure.

FIG. 4D is a fourth partial cross-sectional schematic diagram of a process for manufacturing a semiconductor test structure in a specific example of the disclosure.

### DETAILED DESCRIPTION

Exemplary implementations disclosed in the disclosure will be described in more details below with reference to the accompanying drawings. Although the drawings illustrate exemplary implementations of the disclosure, it should be understood that, the disclosure may be implemented in various forms, and should not be limited by specific implementations described herein. Rather, these implementations are provided so that the disclosure will be thoroughly understood, and will fully convey the scope of the disclosure to those skilled in the art.

In the following description, numerous specific details are set forth for providing more thoroughly understanding of the disclosure. However, it is apparent to those skilled in the art that the disclosure may be implemented without one or more of these details. In other examples, in order to avoid obscuring the disclosure, some well-known technical features in the art are not described. In other words, not all the features in the actual embodiments are described herein, and well-known functions and structures are not described in detail.

In addition, the drawings are merely schematic diagrams of the disclosure, and are not necessarily drawn to scale. Same reference numerals in the accompanying drawings represent the same or similar parts, and are not repeatedly described. Some block diagrams illustrated in the drawings are functional entities, which do not necessarily correspond to physically or logically separated entities. These functional entities can be implemented in the form of software, or in one or more hardware modules or integrated circuits, or in different networks and/or processor apparatuses and/or microprocessor apparatuses.

Flowcharts illustrated in the drawings are for illustration only, and do not necessarily include all operations. For example, some operations may be decomposed, and some operations may be combined or partially combined, and therefore, the actual sequence for executing the operations may be changed according to actual conditions.

It should be understood that spatial relation terms such as “beneath . . . ”, “below . . . ”, “lower”, “under . . . ”, “above . . . ” and “upper” are used herein for conveniently describing relations between one element or feature and other elements or features illustrated in the drawings. It should be understood that the spatial relation terms are intended to include different orientations of the device in use and in operation in addition to the orientations illustrated in the drawings. For example, when the device in the drawing turns over, then the elements or features described as “below other elements” or “under other elements” or “beneath other elements” would be orientated as “above” other elements or features. Therefore, exemplary terms such as “below . . . ” and “beneath . . . ” can include the above and below two orientations. The device may be additionally orientated (rotating 90 degrees or other orientations), and the spatial terms used herein may be explained correspondingly.

The terms used herein are intended to describe detailed description only, and are not to limit the disclosure. As used herein, the singular forms of terms such as “a”, “one”, and “the/this” are also intended to include plural forms, unless the context clearly indicates otherwise. It should also be understood that the terms such as “constitute” and/or “comprise” used in the description specify the presence of the features, entireties, steps, operations, elements and/or assemblies, but do not preclude the presence or addition of one or more other features, entireties, steps, operations, elements, assemblies and/or combinations thereof. As used herein, the term “and/or” includes any and all combinations of the listed items.

In the preparation process of a chip, plasma is used in many process operations. The plasma is a mixture of positive and negative ions and electrons, such as Plasma-Enhanced Chemical Vapor Deposition (PECVD) and plasma etching technologies.

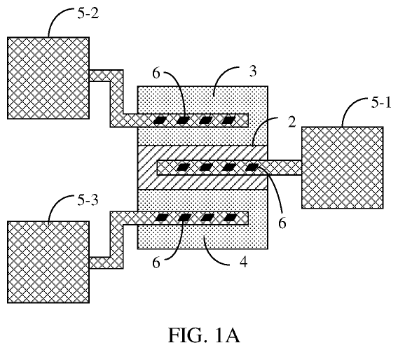

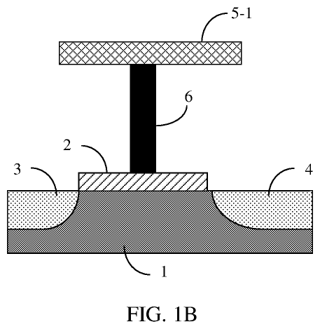

There is a semiconductor test structure provided in some implementations. The semiconductor test structure may be used for evaluating electrical performance of a field-effect transistor. FIG. 1A is a top view of the semiconductor test structure, and FIG. 1B is a section view of the semiconductor test structure. The semiconductor test structure includes a substrate 1. A gate 2 is formed on the substrate 1. A source region 3 and a drain region 4 formed in the substrate 1 are located on two sides of the gate 2, respectively. A metal connection structure is electrically connected with the gate 2, the source region 3 and the drain region 4 through contact plugs 6, respectively. The metal connection structure includes a first metal connection structure 5-1 electrically connected with the gate 2, a second metal connection structure 5-2 electrically connected with the source region 3, and a third metal connection structure 5-3 electrically connected with the drain region 4.

In a preparation process of the field-effect transistor, the huge metal connection structure connected with the gate usually attracts free charges in the plasma. When the charges accumulated in a gate dielectric layer exceed a certain amount, a gate leakage current will be formed in the dielectric layer between the gate and a substrate, and the gate leakage current will damage the gate dielectric layer, resulting in distortion of the electrical performance test of the field-effect transistor.

In view of such situation, the following technical solution in embodiments of the disclosure is provided.

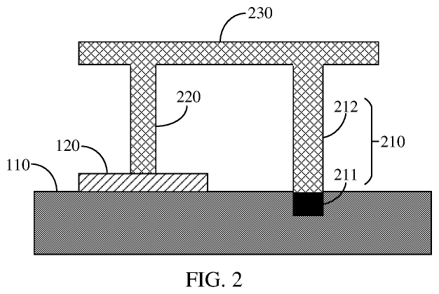

Embodiments of the disclosure provide a semiconductor test structure. FIG. 2 is a schematic structure diagram of a cross-section of a semiconductor test structure provided in embodiments of the disclosure. As illustrated in FIG. 2, the semiconductor test structure includes a field-effect transistor and a metal connection structure.

The field-effect transistor includes a substrate 110 with a first doping type, a gate 120 located on a surface of the substrate and a source region with a second doping type (not shown) and a drain region with the second doping type (not shown) in the substrate 110. The source region and the drain region are located on two sides of the gate 120, respectively.

The metal connection structure is electrically connected with the gate 120. The metal connection structure forms a Schottky contact with the substrate 110.

The first doping type is different from the second doping type. In some embodiments, the first doping type may be P-type doping, and the second doping type may be N-type doping. In other embodiments, a first doping type may be N-type doping, and the second doping type may be P-type doping.

In the preparation process of a field-effect transistor in a semiconductor test structure, a gate of the field-effect transistor forms a Schottky contact with the substrate through a metal connection structure. Therefore, when a gate dielectric layer between the gate and the substrate attracts and accumulates a large variety of charges due to PAE in the preparation process of the field-effect transistor, these charges may cross a Schottky barrier between the metal connection structure and the substrate, to be released through the metal connection structure, so that the field-effect transistor can be protected from PID.

According to embodiments of the disclosure, a metal connection structure electrically connected with the gate and the substrate is provided so as to form a Schottky contact with the substrate form, so that the charges accumulated in the gate can be released and the influence of PID generated in the manufacturing process stage can be eliminated. Meanwhile, the damage of PID on the gate dielectric layer and the influence of PID on the electrical performance of the field-effect transistor at the subsequent test stage can be eliminated.

In the embodiments of the disclosure, the metal connection structure includes: a first contact plug 210 electrically connected with the substrate 110, a second contact plug 220 electrically connected with the gate 120, and a first metal layer 230 connected with the first contact plug 210 and the second contact plug 220. The first metal layer 230 forms a Schottky contact with the substrate 110 through the first contact plug 210.

The first contact plug may form the Schottky contact with the substrate by controlling a metal material in the first contact plug. When the substrate is a P-type doping substrate, the metal material in the first contact plug is a metal material with a work function less than a work function of a material of the substrate. When the substrate is an N-type doping substrate, the metal material in the first contact plug is a metal material with a work function greater than a work function of the material of the substrate.

According to the embodiments of the disclosure, a gate of a field-effect transistor is connected with the substrate through a second contact plug, a first metal layer and a first contact plug, so that in a plasma etching process, charges accumulated in the gate are conducted to the substrate through a path of the second contact plug-the first metal layer-the first contact plug. Therefore, damage of the plasma etching process on the semiconductor test structure can be reduced.

Herein, the first metal layer may be used as a test pad of the semiconductor test structure. A test voltage is applied to the gate through the test pad.

In a specific example, the first contact plug and the second contact plug may be Periphery Contacts (PCs). The first metal layer may be a metal layer (metal 0) electrically connected with the PCs.

In the embodiments of the disclosure, the first contact plug 210 extends into the substrate 110. A material of a part 211 of the first contact plug 210 extending into the substrate 110 is different from a material of the first metal layer 230.

Herein, the material of the part of the first contact plug extending into the substrate may be a metal material such as Al, Cu and Cr.

In the embodiments of the disclosure, a material of a part 212 of the first contact plug 210 not extending into the substrate 110 is the same as a material of the first metal layer 230.

Herein, the material of the part of the first contact plug not extending into the substrate may be a metal material such as W, Cu and Ti.

In the embodiments of the disclosure, the first contact plug 210 extends into the substrate 110. A material of a part 211 of the first contact plug 210 extending into the substrate 110 is the same as a material of the first metal layer 230.

It should be noted that, the substrate is formed by implantation of high concentration ions, thus, the first metal layer itself may form the Schottky contact with the substrate. Therefore, the material of the part of the first contact plug extending into the substrate may be the same as the material of the first metal layer.

In a specific example, a concentration of implanted ions of the substrate with the first doping type may be 2×10¹²/cm² to 2×10¹³/cm².

Herein, the material of the part of the first contact plug extending into the substrate may be a metal material such as W, Cu and Ti. The material of the first metal layer 230 may also be a metal material such as W, Cu and Ti.

In the embodiments of the disclosure, when the field-effect transistor is an N-type field-effect transistor, a work function of a material of the first contact plug 210 is less than a work function of a material of the substrate 110. Therefore, the first contact plug forms a Schottky contact with the substrate.

In the embodiments of the disclosure, when the field-effect transistor is a P-type field-effect transistor, the work function of the material of the first contact plug 210 is greater than the work function of the material of the substrate 110. Therefore, the first contact plug forms a Schottky contact with the substrate.

In some embodiments, when the field-effect transistor is a P-type field-effect transistor, the doping type of the substrate may be P-type doping, and an N-type doping well region may be formed in the substrate. In such case, the field-effect transistor includes a well region located in the substrate, a gate located on a surface of the well region, and a source region with P-type doping and a drain region with P-type doping in well regions which are located on two sides of the gate, respectively. A work function of a material of the first contact plug 210 is greater than a work function of a material of the well region. Therefore, the first contact plug forms a Schottky contact with the well region.

In some embodiments, a gate dielectric layer reliability test for the semiconductor test structure provided in embodiments of the disclosure together with the conventional test structure may be performed. The conventional test structure includes a conventional field-effect transistor and a conventional metal connection structure. The conventional field-effect transistor includes a substrate, a gate located on a surface of the substrate, and a source region and a drain region in the substrate which are located on two sides of the gate, respectively. The conventional metal connection structure includes a second contact plug connected with the gate. When the gate dielectric layer reliability test is performed, a same voltage may be applied to the semiconductor test structure and the conventional test structure, to enable the gate dielectric layer reliability test for the semiconductor test structure and the conventional test structure to be performed under a same test condition. Influence of plasma on reliability of the gate dielectric layer may be evaluated by comparing the test results of the semiconductor test structure and the conventional test structure. Herein, the gate dielectric layer reliability test includes a Time-Dependent Dielectric Breakdown (TDDB) test.

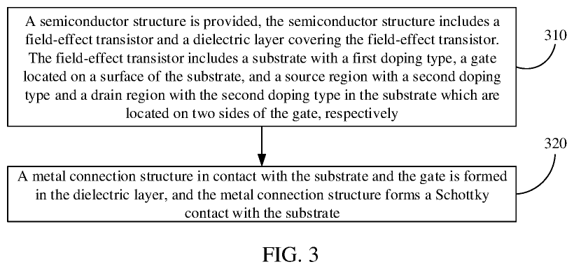

Based on the same technical concept as the foregoing semiconductor test structure, embodiments of the disclosure provide a method for manufacturing the semiconductor test structure. FIG. 3 is a schematic flowchart of an implementation of a method for manufacturing a semiconductor test structure provided in embodiments of the disclosure. As illustrated in FIG. 3, the method mainly includes the following operations.

At operation 310, a semiconductor structure is provided. The semiconductor structure includes a field-effect transistor and a dielectric layer covering the field-effect transistor. The field-effect transistor includes a substrate with a first doping type, a gate located on a surface of the substrate, and a source region with a second doping type and a drain region with the second doping type in the substrate which are located on two sides of the gate, respectively.

At operation 320, a metal connection structure in contact with the substrate and the gate is formed in the dielectric layer. The metal connection structure forms a Schottky contact with the substrate.

In embodiments of the disclosure, the substrate may be an elemental semiconductor material substrate (such as a Si substrate, a Ge substrate), a composite semiconductor material substrate (such as a SiGe substrate), a Silicon On Insulator (SOI) substrate, or a Germanium-On-Insulator (GeOI) substrate, etc.

In embodiments of the disclosure, the substrate with the first doping type may be a P-type doping substrate or an N-type doping substrate.

Herein, the first doping type is different from the second doping type. In some embodiments, a first doping type may be the P-type doping, and the second doping type may be the N-type doping. In some other embodiments, the first doping type may be the N-type doping, and the second doping type may be the P-type doping.

In actual applications, a dielectric layer covering the field-effect transistor may be formed by a deposition process such as Chemical Vapor Deposition (CVD), Physical Vapor Deposition (PVD), and Plasma-Enhanced CVD (PECVD). Herein, a material of the dielectric layer may be an insulating material such as silicon oxide and silicon nitride.

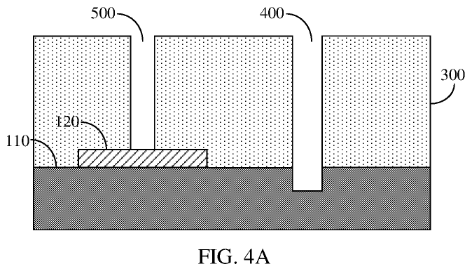

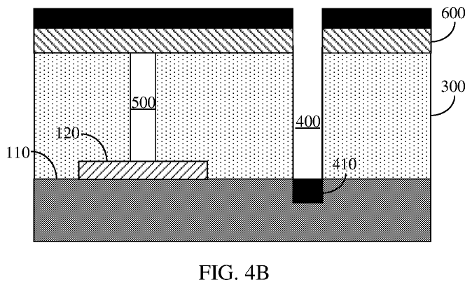

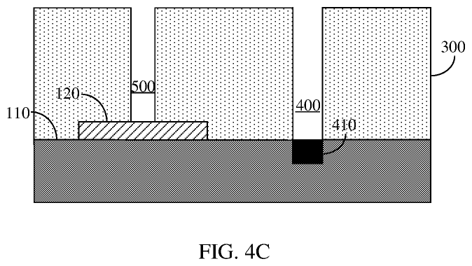

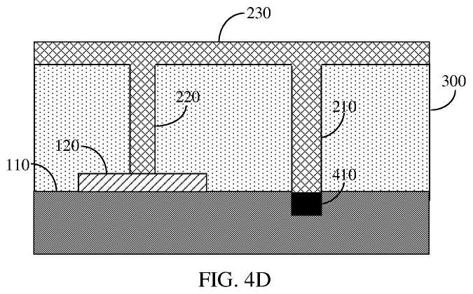

FIG. 4A to FIG. 4D are partial cross-sectional schematic diagrams of a process for manufacturing a semiconductor test structure in a specific example of the disclosure. A method for manufacturing a semiconductor test structure in embodiments of the disclosure is described with reference to FIG. 3 and FIG. 4A to FIG. 4D.

As illustrated in FIG. 4A, the semiconductor structure includes a field-effect transistor and a dielectric layer 300 covering the field-effect transistor. The field-effect transistor includes a substrate with a first doping type 110, a gate 120 located on a surface of the substrate 110, and a source region with a second doping type (not shown) and a drain region with the second doping type (not shown) in the substrate 110 which are located on two sides of the gate 120, respectively. The dielectric layer 300 is etched to form a first contact hole 400 extending to the substrate and a second contact hole 500 extending to the gate. In a specific embodiment, the first contact hole and the second contact hole may be circular holes. It should be noted that the first contact hole and the second contact hole may also be holes of other shapes, such as oval holes and square holes, which are not limited in this disclosure.

According to embodiments of the disclosure, a first contact hole extending to the substrate and a second contact hole extending to the gate are formed by etching synchronously, so that the first contact hole extending to the substrate can be formed without additional processes.

In some embodiments, a first metal material may be directly deposited in the first contact hole and the second contact hole, to form a first contact plug and a second contact plug. Then, a second metal material is deposited on the first contact plug and the second contact plug to form a first metal layer. The first contact plug, the second contact plug and the first metal layer constitute a metal connection structure. The metal connection structure forms a Schottky contact with the substrate through the first contact plug. Herein, the first metal material is the same as the second metal material.

As illustrated in FIG. 4B, a patterned photoresist layer 600 is formed on the semiconductor structure. The patterned photoresist layer 600 covers the second contact hole 500 and exposes the first contact hole 400. The first metal material is deposited in the first contact hole 400 to form a metal material layer 410. A thickness of the metal material layer 410 is less than or equal to a depth of a part of the first contact hole 400 extending into the substrate 110. In a preferred embodiment, a thickness of the metal material layer 410 is equal to the depth of the part of the first contact hole 400 extending into the substrate 110.

In the embodiments of the disclosure, the first metal material may be a metal material such as Al, Cu and Cr.

The patterned photoresist layer 600 and the first metal material located on the patterned photoresist layer 600 are lifted off together by a lift-off process, to form a structure illustrated in FIG. 4C.

As illustrated in FIG. 4D, a second metal material is deposited in the first contact hole 400 and the second contact hole 500 to form a first contact plug 210 and a second contact plug 220. The second metal material is deposited on the first contact plug 210 and the second contact plug 220 to form a first metal layer 230. The first contact plug 210, the second contact plug 220 and the first metal layer 230 constitute the metal connection structure. The metal connection structure forms a Schottky contact with the substrate 110 through the first contact plug 210.

The metal connection structure and the field-effect transistor constitute the semiconductor test structure.

When a thickness of the metal material layer 410 is equal to a depth of a part of the first contact hole 400 extending into the substrate 110, the metal material layer 410 is the part of the first contact plug 210 extending into the substrate 110.

In the embodiments of the disclosure, the second metal material may be a metal material such as W, Cu and Ti.

In some embodiments, the first metal material may be different from the second metal material. In some other embodiments, the first metal material may be the same as the second metal material. Herein, the second metal material may be a metal material such as W, Cu and Ti, and the first metal material may also be a metal material such as W, Cu, and Ti.

It should be noted that the substrate is formed by implantation of high concentration ions, thus, the first metal layer itself may form the Schottky contact with the substrate. Therefore, the first metal material may be the same as the second metal material (a material of the first metal layer). In a specific example, a concentration of implanted ions of the substrate with the first doping type may be 2×10¹²/cm² to 2×10¹³/cm².

In the embodiments of the disclosure, when the field-effect transistor is an N-type field-effect transistor, a work function of the first metal material is less than a work function of a material of the substrate. Therefore, the first contact plug forms a Schottky contact with the substrate.

In the embodiments of the disclosure, when the field-effect transistor is a P-type field-effect transistor, the work function of the first metal material is greater than the work function of the material of the substrate. Therefore, the first contact plug forms a Schottky contact with the substrate.

In some embodiments, when the field-effect transistor is a P-type field-effect transistor, the doping type of the substrate may be P-type doping, and an N-type doping well region may be formed in the substrate. In such case, the field-effect transistor includes a well region located in the substrate, a gate located on a surface of the well region, and a source region with P-type doping and a drain region with P-type doping in well regions which are located on two sides of the gate, respectively. A work function of a material of the first contact plug 210 is greater than a work function of a material of the well region. Therefore, the first contact plug forms a Schottky contact with the well region.

In the preparation process of a field-effect transistor, the gate of the field-effect transistor forms a Schottky contact with the substrate through the metal connection structure. Therefore, when a gate dielectric layer between the gate and the substrate attracts and accumulates a large variety of charges due to PAE in the preparation process of the field-effect transistor, these charges may cross a Schottky barrier between the metal connection structure and the substrate, to be released through the metal connection structure, so that the field-effect transistor can be protected from PID.

According to embodiments of the disclosure, a metal connection structure electrically connected with the gate and the substrate is provided to form a Schottky contact with the substrate form, so that the charges accumulated in the gate can be released and the influence of PID generated in the manufacturing process stage can be eliminated. Meanwhile, the influence of PID on reliability of the gate dielectric layer at the subsequent test stage can be eliminated.

According to the embodiments of the disclosure, a gate of a field-effect transistor is connected with the substrate through a second contact plug, a first metal layer and a first contact plug, so that in the plasma etching process, charges accumulated in the gate are conducted to the substrate through a path of the second contact plug-the first metal layer-the first contact plug. Therefore, damage of the plasma etching process on the semiconductor test structure can be reduced.

The descriptions above are only specific implementations of the disclosure. However, the scope of protection of the disclosure is not limited thereto. Various variations or substitutions apparent to those skilled in the art when considering the technical scope disclosed by the disclosure shall fall within the scope of protection of the disclosure. Therefore, the scope of protection of the disclosure shall be subject to the scope of protection defined by the appended claims.

It should be understood that reference in the description to “one embodiment” or “an embodiment” means that particular features, structures, or characteristics relevant to the embodiments may be included in at least one embodiment of the disclosure. Therefore, “in one embodiment” or “in an embodiment” described in the entire description does not necessarily refer to a same embodiment. In addition, these particular features, structures, or characteristics may be combined in one or more embodiments in any suitable form. It should be understood that, in the embodiments of the disclosure, the serial numbers of the operations do not specify the sequence for executing these operations, and the sequence for executing the operations should be determined according to functions and internal logics thereof, and does not limit the implementation process of the embodiments of the disclosure. The serial numbers of the foregoing embodiments in the disclosure are for description merely and do not represent the preference among the embodiments.

The methods disclosed in the method embodiments provided in the disclosure may be arbitrarily combined without inconsistency, to obtain new method embodiments.

The features disclosed in the product embodiments provided in the disclosure may be arbitrarily combined without inconsistency, to obtain new product embodiments.

The features disclosed in the method or device embodiments provided in the disclosure may be arbitrarily combined without inconsistency, to obtain new method embodiments or device embodiments.

The descriptions above are only specific implementations of the present disclosure. However, the scope of protection of the disclosure is not limited thereto. Various variations or substitutions apparent to those skilled in the art when considering the technical scope disclosed by the disclosure shall fall within the scope of protection of the disclosure. Therefore, the scope of protection of the disclosure shall be subject to the scope of protection defined by the appended claims.

What is claimed is:

1. A semiconductor test structure, comprising a field-effect transistor and a metal connection structure, wherein
the field-effect transistor comprises: a substrate with a first doping type, a gate located on a surface of the substrate, and a source region with a second doping type and a drain region with the second doping type in the substrate, wherein the source region and the drain region are located on two sides of the gate, respectively; and
the metal connection structure is connected with the gate, and the metal connection structure forms a Schottky contact with the substrate.

2. The semiconductor test structure of claim 1, wherein
the metal connection structure comprises: a first contact plug connected with the substrate, a second contact plug connected with the gate, and a first metal layer connected with the first contact plug and the second contact plug;
the first metal layer forms the Schottky contact with the substrate through the first contact plug.

3. The semiconductor test structure of claim 2, wherein
the first contact plug extends into the substrate, and a material of a part of the first contact plug extending into the substrate is different from a material of the first metal layer.

4. The semiconductor test structure of claim 3, wherein
a material of a part of the first contact plug not extending into the substrate is the same as the material of the first metal layer.

5. The semiconductor test structure of claim 2, wherein
the first contact plug extends into the substrate, and a material of a part of the first contact plug extending into the substrate is the same as a material of the first metal layer.

6. The semiconductor test structure of claim 2, wherein
when the field-effect transistor is an N-type field-effect transistor, a work function of a material of the first contact plug is less than a work function of a material of the substrate.

7. The semiconductor test structure of claim 2, wherein
when the field-effect transistor is a P-type field-effect transistor, a work function of a material of the first contact plug is greater than a work function of a material of the substrate.

8. A method for manufacturing a semiconductor test structure, comprising:
providing a semiconductor structure, the semiconductor structure comprising a field-effect transistor and a dielectric layer covering the field-effect transistor, wherein the field-effect transistor comprises a substrate with a first doping type, a gate located on a surface of the substrate, and a source region with a second doping type and a drain region with the second doping type in the substrate, wherein the source region and the drain region are located on two sides of the gate, respectively; and
forming, in the dielectric layer, a metal connection structure in contact with the substrate and the gate, the metal connection structure forming a Schottky contact with the substrate.

9. The method for manufacturing a semiconductor test structure of claim 8, wherein the forming, in the dielectric layer, the metal connection structure in contact with the substrate and the gate comprises:
etching the dielectric layer to form a first contact hole extending to the substrate and a second contact hole extending to the gate; and
depositing a metal material in the first contact hole to form a first contact plug, the first contact plug forming the Schottky contact with the substrate.

10. The method for manufacturing a semiconductor test structure of claim 9, wherein prior to the depositing the metal material in the first contact hole, the method further comprises:
forming a patterned photoresist layer on the semiconductor structure, the patterned photoresist layer covering the second contact hole and exposing the first contact hole.

11. The method for manufacturing a semiconductor test structure of claim 10, wherein the first contact hole extends into the substrate; and
depositing the metal material in the first contact hole to form the first contact plug comprises:
depositing a first metal material in the first contact hole to form a metal material layer, wherein a thickness of the metal material layer is less than or equal to a depth of a part of the first contact hole extending into the substrate.

12. The method for manufacturing a semiconductor test structure of claim 11, wherein after the depositing the metal material in the first contact hole, the method further comprises:
removing the patterned photoresist layer and the first metal material on the patterned photoresist layer by using a lift-off process.

13. The method for manufacturing a semiconductor test structure of claim 12, wherein the depositing the metal material in the first contact hole to form the first contact plug further comprises:
depositing a second metal material in the first contact hole and the second contact hole to form the first contact plug and a second contact plug.

14. The method for manufacturing a semiconductor test structure of claim 13, wherein the first metal material is different from the second metal material.

15. The method for manufacturing a semiconductor test structure of claim 9, wherein the depositing the metal material in the first contact hole to form the first contact plug comprises:
depositing a first metal material in the first contact hole and the second contact hole to form the first contact plug and a second contact plug.

16. The method for manufacturing a semiconductor test structure of claim 13, wherein the forming, in the dielectric layer, the metal connection structure in contact with the substrate and the gate comprises:
depositing the second metal material on the first contact plug and the second contact plug to form a first metal layer, wherein the first contact plug, the second contact plug and the first metal layer constitute the metal connection structure;
the first metal layer forming the Schottky contact with the substrate through the first contact plug.

17. The method for manufacturing a semiconductor test structure of claim 15, wherein the forming, in the dielectric layer, the metal connection structure in contact with the substrate and the gate comprises:
depositing a second metal material on the first contact plug and the second contact plug to form a first metal layer, wherein the first contact plug, the second contact plug and the first metal layer constitute the metal connection structure;
the first metal layer forming the Schottky contact with the substrate through the first contact plug.

18. The method for manufacturing a semiconductor test structure of claim 16, wherein
the first metal material is the same as the second metal material.

19. The method for manufacturing a semiconductor test structure of claim 9, wherein
when the field-effect transistor is an N-type field-effect transistor, a work function of the metal material is less than a work function of a material of the substrate.

20. The method for manufacturing a semiconductor test structure of claim 9, wherein
when the field-effect transistor is a P-type field-effect transistor, a work function of the metal material is greater than a work function of a material of the substrate.
